(19) United States
(12) Patent Application Publication
(10) Pub. No.: US 2024/0186253 A1
(43) Pub. Date: Jun. 6, 2024

(54) PACKAGING STRUCTURE AND PACKAGING METHOD

(71) Applicant: Semiconductor Manufacturing International (Shanghai) Corporation, Shanghai (CN)

(72) Inventor: Jisong JIN, Shanghai (CN)

(73) Assignee: Semiconductor Manufacturing International (Shanghai) Corporation, Shanghai (CN)

(21) Appl. No.: 18/515,513

(22) Filed: Nov. 21, 2023

(30) Foreign Application Priority Data
Dec. 6, 2022 (CN) 202211556505.7

(51) Int. Cl. H01L 23/538; H01L 21/56; H01L 23/00; H01L 23/31; H01L 23/36; H01L 23/48; H01L 25/00; H01L 25/065

(52) U.S. Cl. CPC H01L 23/5381; H01L 21/568; H01L 23/3128; H01L 23/36; H01L 23/481; H01L 24/16; H01L 24/32; H01L 24/73; H01L 24/81; H01L 25/0652; H01L 25/50; H01L 2224/16145; H01L 2224/16225; H01L 2224/32145; H01L 2224/32225; H01L 2224/73204; H01L 2224/81

(57) ABSTRACT

A packaging structure and a packaging method are provided The packaging method includes: bonding a first interconnect chip to a carrier plate in a first area; bonding a first side of a device chip to the carrier plate in a second area, a first chip area of the device chip being adjacent to the first interconnect chip; bonding a second interconnect chip to the first interconnect chip and the first chip area, the second interconnect chip being electrically connected to the first interconnect chip and the device chip, and the second interconnect chip exposing a second chip area; removing the carrier plate; and bonding the first side of the device chip and a side of the first interconnect chip to a bonding surface of a substrate, the first side of the device chip and the first interconnect chip being electrically connected to the substrate.

### CROSS REFERENCE TO RELATED APPLICATIONS

This application is based on and claims priority to Chinese Patent Application No. 202211556505.7, filed on Dec. 6, 2022, the entire content of which is incorporated herein by reference.

### TECHNICAL FIELD

The disclosure relates to the technical field of semiconductor packaging, and in particular to a packaging structure and a packaging method.

### BACKGROUND

For monolithic chip sizes, conventional chip manufacturing technologies are being pushed to their limits. However, applications are long for the ability to use the latest technology to realize large size integrated circuits, and it is a great challenge to realize high-speed and small-volume interconnection between chips.

One current solution is to use smaller integrated circuits with Si bridge chips embedded in the silicon substrate to realize the interconnection between chips through the Si bridge chip, thereby providing heterogeneous chip packaging.

However, the current packaging structures are relatively complex in structure, and the integration level between the chips still needs to be improved.

### SUMMARY

The disclosure relates to a packaging structure and a packaging method to improve the integration level of the packaging structure.

In an aspect of the disclosure, a packaging structure is provided. In a form, the packaging structure includes:

a substrate, including a bonding surface; a device chip, including a first side and a second side opposite to the first side, the first side being bonded to the bonding surface and electrically connected to the substrate, and the second side of the device chip including a first chip area and a second chip area adjacent to the first chip area; a first interconnect chip, bonded to the bonding surface at a side portion of the device chip and electrically connected to the substrate; and a second interconnect chip, bonded to the first chip area of the device chip and the first interconnect chip, the second interconnect chip being electrically connected to the first interconnect chip and the device chip, and the second interconnect chip exposing the second chip area.

In another aspect of the disclosure, a packaging method is provided. In a form, the packaging method includes:
providing a carrier plate, the carrier plate includes a first area and a second area; providing a first interconnect chip; bonding the first interconnect chip to the carrier plate in the first area; providing a device chip, including a first side and a second side opposite to the first side, the second side of the device chip including a first chip area and a second chip area adjacent to the first chip area; bonding the first side of the device chip to the carrier plate in the second area, the first chip area of the device chip being adjacent to the first interconnect chip; providing a second interconnect chip; bonding the second interconnect chip to the first interconnect chip and the first chip area of the device chip, the second interconnect chip being electrically connected to the first interconnect chip and the device chip, and the second interconnect chip exposing the second chip area; removing the carrier plate to expose the first side of the device chip and a side of the first interconnect chip facing away from the second interconnect chip; providing a substrate, including a bonding surface; and bonding the first side of the device chip and the side of the first interconnect chip facing away from the second interconnect chip to the bonding surface of the substrate, the first side of the device chip being electrically connected to the substrate, and the first interconnect chip being electrically connected to the substrate.

Compared with the prior art, the disclosure has the following advantages:

In the packaging structure provided by a form of the disclosure, the device chip includes the first side and the second side opposite to each other; the first side is bonded to the bonding surface and electrically connected to the substrate; the first interconnect chip is bonded to the bonding surface on the side portion of the device chip and electrically connected to the substrate; the second interconnect chip is bonded to the first chip area of the device chip and the first interconnect chip; and the second side of the device chip is electrically connected to the first interconnect chip through the second interconnect chip.

In the form of the disclosure, the first side of the device chip is bonded to the bonding surface to realize electrical connection between the first side of the device chip and the substrate; the device chip is electrically connected to the first interconnect chip through the second interconnect chip located on the second side of the device chip, and the first interconnect chip is electrically connected to the substrate, so as to realize electrical connection between the second side of the device chip and the substrate, so that the first side and the second side of the device chip opposite to each other can both be electrically connected to the substrate, and accordingly the first side and the second side of the device chip can both be electrically connected to the outside through the substrate, thereby improving the integration level of the packaging structure. In addition, the electrical connection between the second side of the device chip and the first interconnect chip is realized through the isolated second interconnect chip, which is beneficial to improve the flexibility of packaging and save the cost.

In the packaging method provided by a form of the disclosure, the first interconnect chip is bonded to the carrier plate in the first area, and the first side of the device chip is bonded to the carrier plate in the second area. The first chip area of the device chip is adjacent to the first interconnect chip. The second interconnect chip is bonded to the first interconnect chip and the first chip area of the device chip; the second interconnect chip is electrically connected to the first interconnect chip and the device chip; and the second interconnect chip exposes the second chip area. Then the first side of the device chip and the side of the first interconnect chip facing away from the second interconnect chip are bonded to the bonding surface of the substrate, the first side of the device chip is electrically connected to the substrate, and the first interconnect chip is electrically connected to the substrate.

In the form of the disclosure, the first side of the device chip is bonded to the bonding surface to realize electrical connection between the first side of the device chip and the substrate; the device chip is electrically connected to the first interconnect chip through the second interconnect chip located on the second side of the device chip, and the first interconnect chip is electrically connected to the substrate, so as to realize electrical connection between the second side of the device chip and the substrate, so that the first side and the second side of the device chip opposite to each other can both be electrically connected to the substrate, and accordingly the first side and the second side of the device chip can both be electrically connected to the outside through the substrate, thereby improving the integration level of the packaging structure. In addition, the electrical connection between the second side of the device chip and the first interconnect chip is realized through the isolated second interconnect chip, which is beneficial to improve the flexibility of packaging and save the cost.

### BRIEF DESCRIPTION OF THE DRAWINGS

FIG. 1 is a schematic structural view of a packaging structure according to a form of the disclosure; and

FIG. 2 to FIG. 11 are schematic structural views corresponding to steps of a packaging method according to a form of the disclosure.

### DETAILED DESCRIPTION

Traditionally, only the front side of the two opposite sides of a chip is electrically connected to the outside. With the back side power delivery network (BSPDN) technology, the back side of the chip is also formed with interconnect pads for electrical connection to the outside, for example, as in the document 10.1109/TED.2019.2954301. However, at present, there is no method for electrically leading out the back side of the chip to electrically connect both the front side and back side of the chip to the outside, which makes it difficult to improve the integration level of packaging.

In order to address the technical problems, a form of the disclosure provides a packaging structure. A device chip includes a first side and a second side opposite to each other; the first side is bonded to a bonding surface and electrically connected to a substrate; a first interconnect chip is bonded to the bonding surface at a side portion of the device chip and electrically connected to the substrate; a second interconnect chip is bonded to a first chip area of the device chip and the first interconnect chip; and the second side of the device chip is electrically connected to the first interconnect chip through the second interconnect chip. In the form of the disclosure, the first side of the device chip is bonded to the bonding surface to realize electrical connection between the first side of the device chip and the substrate; the device chip is electrically connected to the first interconnect chip through the second interconnect chip located on the second side of the device chip, and the first interconnect chip is electrically connected to the substrate, so as to realize electrical connection between the second side of the device chip and the substrate, so that the first side and the second side of the device chip opposite to each other can both be electrically connected to the substrate, and accordingly the first side and the second side of the device chip can both be electrically connected to the outside through the substrate, thereby improving the integration level of the packaging structure. In addition, the electrical connection between the second side of the device chip and the first interconnect chip is realized through the isolated second interconnect chip, which is beneficial to improve the flexibility of packaging and save the cost.

To make the foregoing objectives, features, and advantages of the disclosure more apparent and easier to understand, exemplary forms of the disclosure are described in detail below with reference to the accompanying drawings.

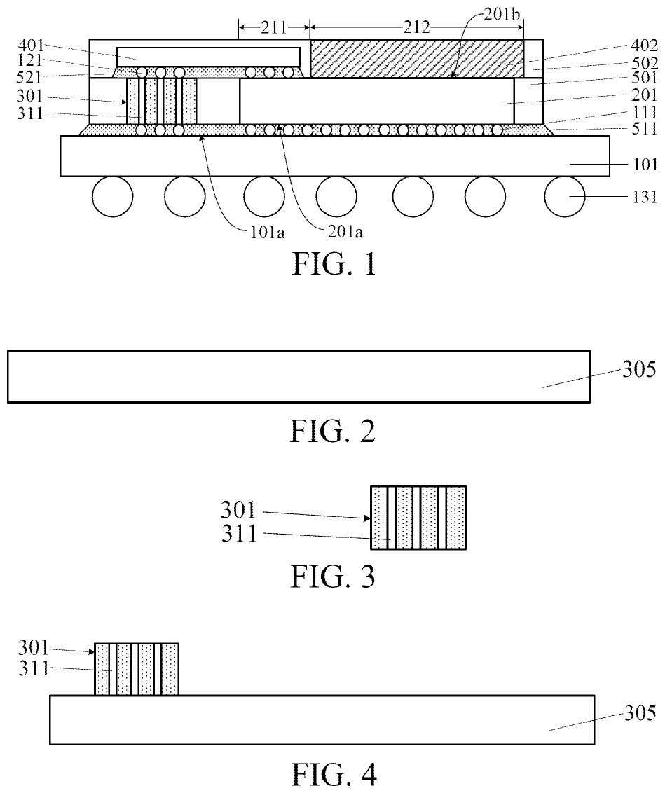

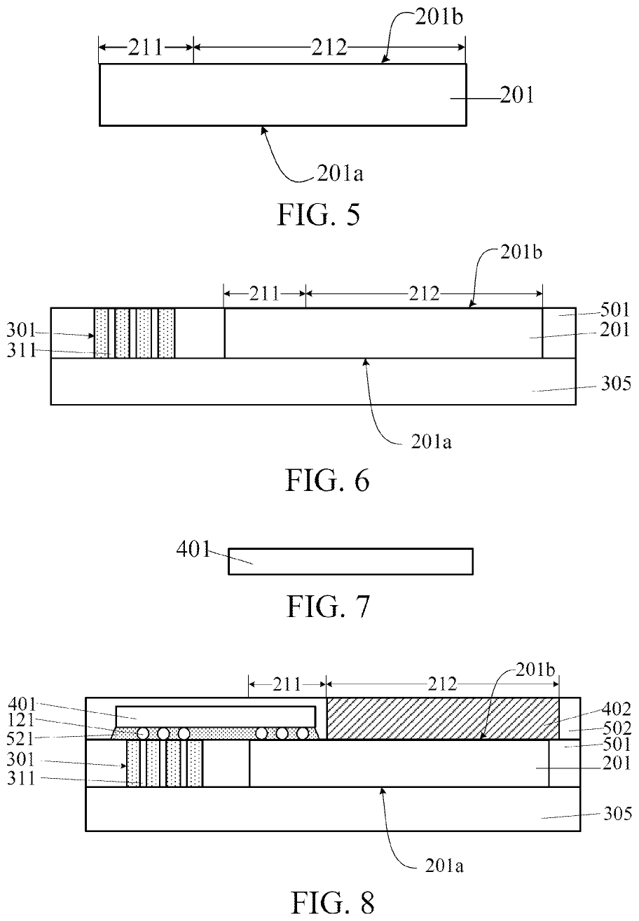

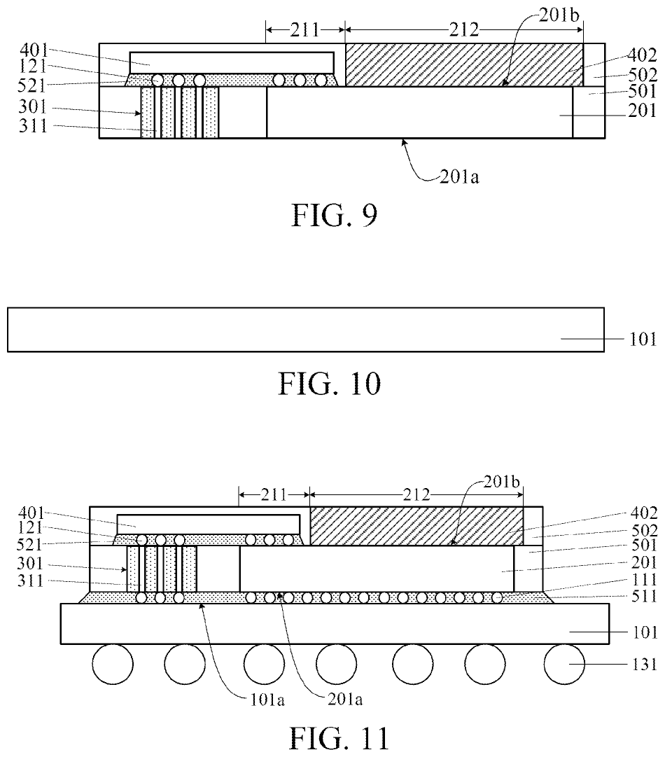

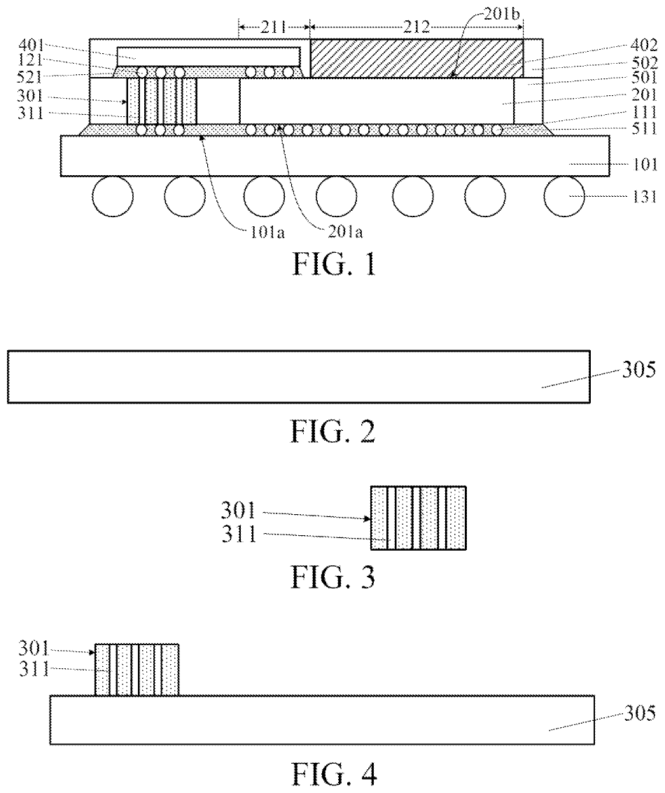

FIG. 1 is a schematic structural view of a form of a packaging structure according to the disclosure.

The packaging structure includes: a substrate 101, which includes a bonding surface 101a; a device chip 201, which includes a first side 201a and a second side 201b opposite to each other, the first side 201a is bonded to the bonding surface 101a and electrically connected to the substrate 101, and the second side 201b of the device chip 201 includes a first chip area 211 and a second chip area 212 adjacent to each other; a first interconnect chip 301, which is bonded to the bonding surface 101a at a side portion of the device chip 201 and electrically connected to the substrate 101; and a second interconnect chip 401, which is bonded to the first chip area 211 of the device chip 201 and the first interconnect chip 301, the second interconnect chip 401 is electrically connected to the first interconnect chip 301 and the device chip 201, and the second interconnect chip 401 exposes the second chip area 212.

The substrate 101 is used for realizing bonding to the device chip 201 and bonding to the first interconnect chip 301, so as to realize packaging integration and electrical integration of the device chip 201, the first interconnect chip 301 and the substrate 101. The substrate 101 is also used for providing a process operation basis for realizing bonding to the device chip 201 and bonding to the first interconnect chip 301.

Specifically, the bonding surface 101a of the substrate 101 is a process operation platform.

In this form, the substrate 101 is a PCB (printed circuit board).

The device chip 201 is used for electrical connection to the substrate 101, so as to form the corresponding packaging structure to realize corresponding functions.

In this form, the first side 201a is bonded to the bonding surface 101a and electrically connected to the substrate 101 to realize electrical connection between the first side 201a of the device chip 201 and the substrate 101.

In this form, the first side 201a is a front side of the chip to accordingly realize electrical connection between the front side of the chip and the substrate 101.

The front side of the chip is a side facing a device in the chip.

In an example, the first side 201a of the device chip 201 is bonded to the bonding surface 101a of the substrate 101 to realize signal communication between the device chip 201 and the substrate 101.

In this form, the second side 201b of the device chip 201 includes a first chip area 211 and a second chip area 212 adjacent to each other. The first chip area 211 is used for bonding the second interconnect chip 401, so as to realize electrical connection between the device chip 201 and the second interconnect chip 401.

In this form, the second chip area 212 is used for attaching a heat sink, so as to better realize heat dissipation of the device chip 201, which is beneficial to improve the heat dissipation performance of the packaging structure.

In this form, in order to facilitate bonding of the second interconnect chip 401 to the first interconnect chip 301 and to the device chip 201, the first chip area 211 of the device chip 201 is adjacent to the first interconnect chip 301.

The first interconnect chip 301 is used for electrical connection to the substrate 101, so as to realize electrical connection between the second interconnect chip 401 and the substrate 101.

In this form, a first interconnection structure 311 running through the first interconnect chip 301 is formed in the first interconnect chip 301, and the substrate 101 is electrically connected to the second interconnect chip 401 through the first interconnection structure 311.

The first interconnection structure 311 is used as an electrical connection structure to realize electrical connection between the second interconnect chip 401 and the substrate 101.

In this form, the first interconnection structure 311 is a through-silicon-via (TSV) structure. With the TSV structure, the stacking density of the first interconnect chip 301 in three-dimensional directions can be increased, and the overall dimension of the first interconnect chip 301 is smaller. Moreover, the speed of the chip is greatly improved, and the power consumption of the chip is reduced.

In this form, a material of the first interconnection structure 311 is a metal material, for example, one or more of copper, aluminum, tungsten, cobalt, nickel, titanium, tantalum, titanium nitride and tantalum nitride.

In this form, a top surface of the first interconnect chip 301 is flush with the second side 201b of the device chip 201, so as to reduce a height difference between the first interconnect chip 301 and the second side 201b of the device chip 201, thereby facilitating bonding of the second interconnect chip 401 to the first interconnect chip 301 and the first chip area 211.

In this form, the packaging structure further includes: a first packaging layer 501, which covers side walls of the device chip 201 and the first interconnect chip 301.

The first packaging layer 501 is used for protecting structures of the device chip 201 and the first interconnect chip 301 and also plays a sealing role to isolate the device chip 201 and the first interconnect chip 301 from an external environment. Moreover, the first packaging layer 501 is also used for realizing packaging integration of the device chip 201 and the first interconnect chip 301.

In this form, a material of the first packaging layer 501 is a molding material, for example, epoxy resin. The epoxy resin has the advantages of low shrinkage, good binding property, good corrosion resistance, excellent electrical properties, low cost and the like, and is beneficial to improve the packaging effect of the first packaging layer 501 on the device chip 201 and the first interconnect chip 301. In other forms, the first packaging layer may be made of other appropriate packaging materials.

In this form, the packaging structure further includes: second conductive bumps 111, which are located between the device chip 201 and the substrate 101 and between the first interconnect chip 301 and the substrate 101, electrically connect the device chip 201 to the substrate 101, and electrically connect the first interconnect chip 301 to the substrate 101.

The second conductive bumps 111 are used for realizing electrical connection between the substrate 101 and the device chip 201 and realizing electrical connection between the first interconnect chip 301 and the substrate 101.

In this form, a material of the second conductive bump 111 includes one or more of tin, copper, aluminum, tungsten, cobalt, nickel, titanium, tantalum, titanium nitride and tantalum nitride. In an example, the material of the second conductive bump 111 is tin.

For example, the second conductive bump 111 may be C4 (Controlled Collapse Chip Connection), and has excellent electrical properties and thermal characteristics. Moreover, in a case of the same pitch between the second conductive bumps 111, the I/O number can be very high, and not limited by the size of the redistribution structure. Besides, the second conductive bump is suitable for mass production, and the size and weight are greatly reduced.

In other forms, the second conductive bump may be a ubump.

In this form, the packaging structure further includes: a second sealing layer 511, which fills a gap between the adjacent second conductive bumps 111 and covers the second conductive bumps 111.

The second sealing layer 511 is used for realizing sealing between the device chip 201 and the substrate 101 and sealing between the first interconnect chip 301 and the substrate 101, and also used for sealing the second conductive bumps 111.

In an example, the second sealing layer 511 is an underfill.

In this form, the first interconnect chip 301 is bonded to the bonding surface 101a at the side portion of the device chip 201, so that the device chip 201 and the first interconnect chip 301 can be sealed in the same step, which is beneficial to improve the process efficiency.

The second interconnect chip 401 is used for realizing electrical connection between the second side 201b of the device chip 201 and the first interconnect chip 301, thereby electrically leading out the second side 201b of the device chip 201.

In this form, the second side 201b is a back side of the chip, thereby realizing electrical connection between the back side of the device chip 201 and the substrate 101.

The back side of the chip is a side facing away from the device in the chip.

In this form, the first side 201a of the device chip 201 is bonded to the bonding surface 101a to realize electrical connection between the first side 201a of the device chip 201 and the substrate 101. The device chip 201 is electrically connected to the first interconnect chip 301 through the second interconnect chip 401 located on the second side 201b of the device chip 201, and the first interconnect chip 301 is electrically connected to the substrate 101, so as to realize electrical connection between the second side 201b of the device chip 201 and the substrate 101, so that the first side 201a and the second side 201b of the device chip 201 opposite to each other can both be electrically connected to the substrate 101, and accordingly the first side 201a and the second side 201b of the device chip 201 can both be electrically connected to the outside through the substrate 101, thereby improving the integration level of the packaging structure.

In addition, in this form, the electrical connection between the second side 201b of the device chip 201 and the first interconnect chip 301 is realized through the isolated second interconnect chip 401, which is beneficial to improve the flexibility of packaging and save the cost.

During the actual process, this form is particularly applicable to the case where a buried power rail (BPR) structure and a power delivery network (PDN) structure are used, which has high requirements for chip size and integration level.

In an example, the first side 201a of the device chip 201 is bonded to the bonding surface 101a to realize signal communication between the first side 201a of the device chip 201 and the substrate 101. The device chip 201 is electrically connected to the first interconnect chip 301 through the second interconnect chip 401 located on the second side 201b of the device chip 201, and the first interconnect chip 301 is electrically connected to the substrate 101, so as to realize electrical connection between the second side 201b of the device chip 201 and the substrate 101, thereby realizing power supply to the device chip 201 through the substrate 101.

In this form, a second interconnection structure (not shown) is formed in the second interconnect chip 401, and the second interconnect chip 401 is electrically connected to the device chip 201 through the second interconnection structure.

In this form, the second interconnection structure is used for electrical connection to the device chip 201 to electrically lead out the back side of the device chip 201, and is electrically connected to the first interconnect chip 301, thereby realizing electrical connection between the first interconnect chip 301 and the device chip 201.

In this form, a material of the second interconnection structure is a metal material, for example, one or more of copper, aluminum, tungsten, cobalt, nickel, titanium, tantalum, titanium nitride and tantalum nitride.

In this form, the second interconnect chip 401 includes a chip bridge (Si bridge), or the second interconnect chip 401 includes a chip including a plurality of re-distributed layers (RDL bridge). The second interconnect chip 401 is a single isolated die, which is low in price and beneficial to save the cost.

In this form, the second interconnect chip 401 has a small size. Therefore, while realizing the electrical connection between the first interconnect chip 301 the device chip 201, the second interconnect chip 401 also exposes a part of area of the second side of the device chip 201, i.e., the second interconnect chip 401 exposes the second chip area 212.

In this form, the packaging structure further includes: first conductive bumps 121, which are located between the device chip 201 and the second interconnect chip 401 and between the first interconnect chip 301 and the second interconnect chip 401, electrically connect the device chip 201 to the second interconnect chip 401, and electrically connect the first interconnect chip 301 to the second interconnect chip 401.

The first conductive bumps 121 are used for realizing electrical connection between the second interconnect chip 401 and the device chip 201 and electrical connection between the first interconnect chip 301 and the second interconnect chip 401.

In this form, a material of the first conductive bump 121 includes one or more of tin, copper, aluminum, tungsten, cobalt, nickel, titanium, tantalum, titanium nitride and tantalum nitride. In an example, the material of the first conductive bump 121 is tin.

For example, the first conductive bump 121 may be C4 (Controlled Collapse Chip Connection), and has excellent electrical properties and thermal characteristics. Moreover, in a case of the same pitch between the first conductive bumps 121, the I/O number can be very high, and not limited by the size of the redistribution structure. Besides, the first conductive bump is suitable for mass production, and the size and weight are greatly reduced.

In other forms, the first conductive bump may be a ubump.

In this form, the packaging structure further includes: a first sealing layer 521, which fills a gap between the adjacent first conductive bumps 121 and covers the first conductive bumps 121.

The first sealing layer 521 is used for realizing sealing between the device chip 201 and the second interconnect chip 401 and sealing between the first interconnect chip 301 and the second interconnect chip 401, and also used for sealing the first conductive bumps 121.

In an example, the first sealing layer 521 is an underfill.

In this form, the packaging structure further includes: a heat sink 402, which is attached to the second chip area 212 of the device chip 201.

In this form, by bonding the second interconnect chip 401 to the first chip area 211 and attaching the heat sink 402 to the second chip area 212, the electrical connection between the device chip 201 and the first interconnect chip 301 is realized, and an idle area of the device chip 201 is fully utilized, thereby improving the heat dissipation ability of the packaging structure without occupying additional chip area, and accordingly improving the performance of the packaging structure.

In an example, a material of the heat sink 402 includes silicon. Silicon has good heat dissipation performance and is a material commonly used in the field of semiconductors, which is beneficial to improve the process compatibility and control the cost. In other forms, the heat sink may be other materials having good heat dissipation ability.

In an example, the heat sink 402 is in contact with the device chip 201 to improve the heat dissipation effect on the device chip 201. In other forms, the heat sink may not be in contact with the device chip.

In this form, the packaging structure further includes: a second packaging layer 502, which is located on the first packaging layer 501 and covers the second interconnect chip 401 and a side wall of the heat sink 402, and the second packaging layer 502 exposes the heat sink 402.

The second packaging layer 502 is used for protecting structures of the second interconnect chip 401 and the heat sink 402 and also plays a sealing role. Moreover, the second packaging layer 502 is also used for realizing packaging integration between the second interconnect chip 401 and the heat sink 402 and between the device chip 201 and the first interconnect chip 301.

In this form, the second packaging layer 502 exposes the heat sink 402, so that the heat sink 402 can play a role of dissipating heat.

In this form, a material of the second packaging layer 502 is a molding material, for example, epoxy resin. The epoxy resin has the advantages of low shrinkage, good binding property, good corrosion resistance, excellent electrical properties, low cost and the like, and is beneficial to improve the packaging effect of the second packaging layer 502 on the second interconnect chip 401 and the heat sink 402. In other forms, the second packaging layer may be made of other appropriate packaging materials.

In this form, the packaging structure further includes: third conductive bumps 131, which are located on a surface of one side of the substrate 101 facing away from the bonding surface 101a. The third conductive bumps 131 are used for realizing electrical connection between the packaging structure and an external circuit.

The electrical connection between the packaging structure and the external circuit is realized through the third conductive bumps 131, so as to realize electrical connection between both the first side and the second side of the device chip 201 and the external circuit.

More specifically, the front side and the back side of the chip can both be electrically connected to the external circuit through the third conductive bumps 131.

In this form, a material of the third conductive bump 131 includes one or more of tin, copper, aluminum, tungsten, cobalt, nickel, titanium, tantalum, titanium nitride and tantalum nitride. In an example, the material of the third conductive bump 131 is tin.

For example, the third conductive bump 131 may be C4 (Controlled Collapse Chip Connection), and has excellent electrical properties and thermal characteristics. Moreover, in a case of the same pitch between the third conductive bumps 131, the I/O number can be very high, and not limited by the size of the redistribution structure. Besides, the third conductive bump is suitable for mass production, and the size and weight are greatly reduced.

In other forms, the third conductive bump may be a ball grid array (BGA) structure.

Accordingly, a form of the disclosure further provides a packaging method. FIG. 2 to FIG. 11 are schematic structural views corresponding to steps of a form of a packaging method according to the disclosure.

Referring to FIG. 2, a carrier plate 305 is provided. The carrier plate 305 includes a first area (not shown) and a second area (not shown).

The carrier plate 305 is used for providing a process operation platform for subsequent packaging steps. The carrier plate 305 is also used for providing carrying and supporting functions for subsequent process steps.

More specifically, the carrier plate 305 is used for carrying a first interconnect chip and a device chip.

The first area is used for bonding the first interconnect chip, so as to realize electrical connection to conductive pillars. The second area is used for bonding the device chip, so as to realize electrical connection to the device chip.

In this form, the carrier plate 305 is a carrier wafer. In other forms, the carrier plate may alternatively be other types of bases. In this form, a material of the carrier plate may include one or more of silicon, glass, silicon oxide and aluminum oxide.

Referring to FIG. 3, a first interconnect chip 301 is provided.

The first interconnect chip 301 is used for subsequent electrical connection to a substrate, so as to realize electrical connection between a second interconnect chip bonded to the first interconnect chip 301 and the substrate.

In this form, a first interconnection structure 311 running through the first interconnect chip 301 is formed in the first interconnect chip 301.

The first interconnection structure 311 is used as an electrical connection structure to realize subsequent electrical connection between the second interconnect chip and the substrate.

In this form, the first interconnection structure 311 is a through-silicon-via (TSV) structure. With the TSV structure, the stacking density of the first interconnect chip 301 in three-dimensional directions is larger, and the overall dimension is smaller. Moreover, the speed of the chip is greatly improved, and the power consumption of the chip is reduced.

In this form, a material of the first interconnection structure 311 is a metal material, for example, one or more of copper, aluminum, tungsten, cobalt, nickel, titanium, tantalum, titanium nitride and tantalum nitride.

Referring to FIG. 4, the first interconnect chip 301 is bonded to the carrier plate 305 in the first area.

The first interconnect chip 301 is bonded to the carrier plate 305 in the first area, thereby facilitating subsequent packaging integration between the first interconnect chip 301 and the device chip on the carrier plate 305.

In an example, the first interconnect chip 301 is temporarily bonded to the carrier plate 305 in the first area, so as to reduce the difficulty in subsequent removal of the carrier plate 305.

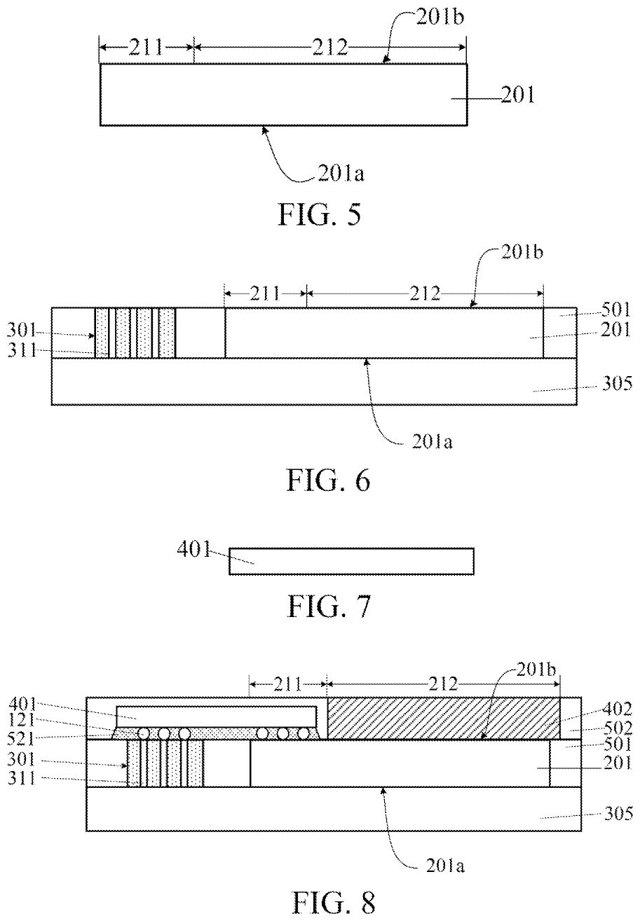

Referring to FIG. 5, a device chip 201 is provided. The device chip includes a first side 201a and a second side 201b opposite to each other, and the second side 201b of the device chip 201 includes a first chip area 211 and a second chip area 212 adjacent to each other.

The device chip 201 is used for electrical connection to the substrate, so as to form the corresponding packaging structure to realize corresponding functions.

In this form, the first side 201a is a front side of the chip, and the second side 201b is a back side of the chip.

In this form, the front side of the chip is a side facing a device in the chip, and the back side of the chip is a side facing away from the device in the chip.

In this form, the second side 201b of the device chip 201 includes the first chip area 211 and the second chip area 212 adjacent to each other. The first chip area 211 is used for bonding the second interconnect chip, so as to realize electrical connection between the device chip 201 and the second interconnect chip.

In this form, the second chip area 212 is used for attaching a heat sink, so as to better realize heat dissipation of the device chip 201, which is beneficial to improve the heat dissipation performance of the packaging structure.

Referring to FIG. 6, the first side 201a of the device chip 201 is bonded to the carrier plate 305 in the second area. The first chip area 211 of the device chip 201 is adjacent to the first interconnect chip 301.

The first side 201a of the device chip 201 is bonded to the carrier plate 305 in the second area, thereby facilitating subsequent packaging integration of the device chip 201 and the first interconnect chip 301.

Besides, the first side 201a is bonded to the carrier plate 305 in the second area, so that the first side 201a can be exposed after the carrier plate 305 is removed subsequently, thereby facilitating subsequent bonding between the first side 201a and the substrate.

More specifically, in this form, the first side 201a of the device chip 201 is temporarily bonded to the carrier plate 305 in the second area, so as to reduce the process difficulty in subsequent removal of the carrier plate 305.

In an example, after bonding the first interconnect chip 301 to the carrier plate 305, the device chip 201 is bonded to the carrier plate 305. In other forms, the process sequence of bonding the first interconnect chip and the device chip to the carrier plate may be adjusted flexibly.

In this form, in order to facilitate bonding of the second interconnect chip 401 to the first interconnect chip 301 and to the device chip 201, the first chip area 211 of the device chip 201 is adjacent to the first interconnect chip 301.

In this form, after bonding the first interconnect chip 301 to the carrier plate 305 in the first area and bonding the first side 201a of the device chip 201 to the carrier plate 305, a top surface of the first interconnect chip 301 is flush with the second side 201b of the device chip 201, so as to reduce a height difference between the first interconnect chip 301 and the second side 201b of the device chip 201, thereby facilitating bonding of the second interconnect chip 401 to the first interconnect chip 301 and the first chip area 211.

Still referring to FIG. 6, the packaging method further includes: after bonding the first interconnect chip 301 to the carrier plate 305 in the first area and bonding the first side 201a of the device chip 201 to the carrier plate 305 and before bonding the second interconnect chip to the first interconnect chip and the first chip area of the device chip, forming a first packaging layer 501 covering side walls of the first interconnect chip 301 and the device chip 201 on the carrier plate.

The first packaging layer 501 is used for protecting structures of the device chip 201 and the first interconnect chip 301 and also plays a sealing role to isolate the device chip 201 and the first interconnect chip 301 from an external environment. Moreover, the first packaging layer 501 is also used for realizing packaging integration of the device chip 201 and the first interconnect chip 301.

In this form, a material of the first packaging layer 501 is a molding material, for example, epoxy resin. The epoxy resin has the advantages of low shrinkage, good binding property, good corrosion resistance, excellent electrical properties, low cost and the like, and is beneficial to improve the packaging effect of the first packaging layer 501 on the device chip 201 and the first interconnect chip 301. In other forms, the first packaging layer may be made of other appropriate packaging materials.

In an example, the first packaging layer 501 is formed by a molding process. In other forms, the first packaging layer may alternatively be formed by other appropriate processes based on actual process demands.

Referring to FIG. 7, a second interconnect chip 401 is provided.

The second interconnect chip 401 is used for realizing subsequent electrical connection between the second side 201b of the device chip 201 and the first interconnect chip 301, thereby electrically leading out the second side 201b of the device chip 201.

In this form, in the step of providing the second interconnect chip 401, a second interconnection structure (not shown) is formed in the second interconnect chip 401, and the second interconnect chip 401 is electrically connected to the device chip 201 through the second interconnection structure.

In this form, the second interconnection structure is used for electrical connection to the device chip 201 to electrically lead out the back side of the device chip 201, and is electrically connected to the first interconnect chip 301, thereby realizing electrical connection between the first interconnect chip 301 and the device chip 201.

In this form, a material of the second interconnection structure is a metal material, for example, one or more of copper, aluminum, tungsten, cobalt, nickel, titanium, tantalum, titanium nitride and tantalum nitride.

In this form, the second interconnect chip 401 includes a chip bridge (Si bridge), or the second interconnect chip 401 includes a chip including a plurality of re-distributed layers (RDL bridge). The second interconnect chip 401 is a single isolated die, which is low in price and beneficial to save the cost.

Referring to FIG. 8, the second interconnect chip 401 is bonded to the first interconnect chip 301 and the first chip area 211 of the device chip 201. The second interconnect chip 401 is electrically connected to the first interconnect chip 301 and the device chip 201, and the second interconnect chip 401 exposes the second chip area 212.

The second interconnect chip 401 is used for realizing electrical connection between the second side 201b of the device chip 201 and the first interconnect chip 301.

In this form, the second side 201b is a back side of the chip, thereby realizing electrical connection between the back side of the device chip 201 and the substrate 101.

The back side of the chip is a side facing away from the device in the chip.

In this form, the second interconnect chip 401 has a small size. Therefore, while realizing the electrical connection between the first interconnect chip 301 the device chip 201, the second interconnect chip 401 also exposes a part of area of the second side 201b of the device chip 201, i.e., the second interconnect chip 401 exposes the second chip area 212.

In this form, in the step of bonding the second interconnect chip 401 to the first interconnect chip 301 and the first chip area 211 of the device chip 201, the second interconnect chip 401 is electrically connected to the first interconnection structure.

Specifically, in this form, in the step of bonding the second interconnect chip 401 to the first interconnect chip 301 and the first chip area 211 of the device chip 201, the second interconnect chip 401 is electrically connected to the device chip 201 through the second interconnection structure.

In this form, the step of bonding the second interconnect chip 401 to the first interconnect chip 301 and the first chip area 211 of the device chip 201 includes: forming first conductive bumps 121 on the second interconnect chip 401, and/or, on the first chip area 211 of the device chip 201 and a side of the first interconnect chip 301 facing away from the carrier plate 305; and realizing bonding of the second interconnect chip 401 to the device chip 201 and the first interconnect chip 301 through the first conductive bumps 121, the first conductive bumps 121 electrically connect the second interconnect chip 401 to the device chip 201 and electrically connect the second interconnect chip 401 to the first interconnect chip 301.

The first conductive bumps 121 are used for realizing electrical connection between the second interconnect chip 401 and the device chip 201 and electrical connection between the first interconnect chip 301 and the second interconnect chip 401.

In this form, a material of the first conductive bump 121 includes one or more of tin, copper, aluminum, tungsten, cobalt, nickel, titanium, tantalum, titanium nitride and tantalum nitride. In an example, the material of the first conductive bump 121 is tin.

For example, the first conductive bump 121 may be C4 (Controlled Collapse Chip Connection), and has excellent electrical properties and thermal characteristics. Moreover, in a case of the same pitch between the first conductive bumps 121, the I/O number can be very high, and not limited by the size of the redistribution structure. Besides, the first conductive bump is suitable for mass production, and the size and weight are greatly reduced.

In other forms, the first conductive bump may be a ubump.

In this form, after bonding the second interconnect chip 401 to the first interconnect chip 301 and the first chip area 211 of the device chip 201, the packaging method further includes: filling a gap between the adjacent first conductive bumps 121 with a first sealing layer 521. The first sealing layer 521 covers the first conductive bumps 121.

The first sealing layer 521 is used for realizing sealing between the device chip 201 and the second interconnect chip 401 and sealing between the first interconnect chip 301 and the second interconnect chip 401, and also used for sealing the first conductive bumps 121. In an example, the first sealing layer 521 is an underfill.

Still referring to FIG. 8, after bonding the first interconnect chip 301 to the carrier plate 305 in the first area and bonding the first side 201a of the device chip 201 to the carrier plate 305 and before removing the carrier plate 305, a heat sink 402 is provided; and the heat sink 402 is attached to the second chip area 212 of the device chip 201.

In this form, by bonding the second interconnect chip 401 to the first chip area 211 and attaching the heat sink 402 to the second chip area 212, the electrical connection between the device chip 201 and the first interconnect chip 301 is realized, and an idle area of the device chip 201 is fully utilized, thereby improving the heat dissipation ability of the packaging structure without occupying additional chip area, and accordingly improving the performance of the packaging structure.

In an example, a material of the heat sink 402 includes silicon. Silicon has good heat dissipation performance and is a material commonly used in the field of semiconductors, which is beneficial to improve the process compatibility and control the cost. In other forms, the heat sink may be other materials having good heat dissipation ability.

In an example, the heat sink 402 is in contact with the device chip 201 to improve the heat dissipation effect on the device chip 201. In other forms, the heat sink may not be in contact with the device chip.

In an example, after bonding the second interconnect chip 401 to the first interconnect chip 301 and the first chip area 211 of the device chip 201, the heat sink 402 is attached to the second chip area 212 of the device chip 201. In other forms, the sequence of bonding the second interconnect chip to the first interconnect chip and the first area of the device chip and attaching the heat sink to the second chip area of the device chip may be adjusted flexibly based on actual process demands.

Still referring to FIG. 8, the packaging method further includes: after bonding the second interconnect chip 401 to the first interconnect chip 301 and the first chip area 211 of the device chip 201 and attaching the heat sink 402 to the second chip area 212 of the device chip 201 and before removing the carrier plate 305, forming a second packaging layer 502 covering the second interconnect chip 401 and a side wall of the heat sink 402 on the first packaging layer 501. The second packaging layer 502 exposes the heat sink 402.

The second packaging layer 502 is used for protecting structures of the second interconnect chip 401 and the heat sink 402 and also plays a sealing role. Moreover, the second packaging layer 502 is also used for realizing packaging integration between the second interconnect chip 401 and the heat sink 402 and between the device chip 201 and the first interconnect chip 301.

In this form, the second packaging layer 502 exposes the heat sink 402, so that the heat sink 402 can play a role of dissipating heat.

In this form, a material of the second packaging layer 502 is a molding material, for example, epoxy resin. The epoxy resin has the advantages of low shrinkage, good binding property, good corrosion resistance, excellent electrical properties, low cost and the like, and is beneficial to improve the packaging effect of the second packaging layer 502 on the second interconnect chip 401 and the heat sink 402. In other forms, the second packaging layer may be made of other appropriate packaging materials.

In an example, the second packaging layer 502 is formed by a molding process. In other forms, the second packaging layer may alternatively be formed by other appropriate processes.

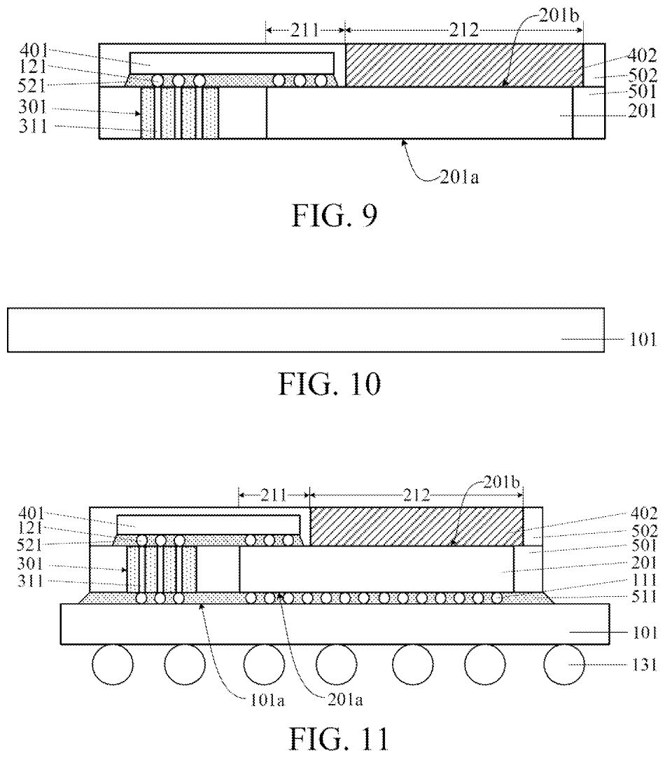

Referring to FIG. 9, the carrier plate 305 is removed to expose the first side 201a of the device chip 201 and a side of the first interconnect chip 301 facing away from the second interconnect chip 401, thereby facilitating subsequent bonding of the first side 201a of the device chip 201 and the side of the first interconnect chip 301 facing away from the second interconnect chip 401 to the substrate.

In an example, the carrier plate 305 may be removed by debonding, thereby reducing the process difficulty in removal of the carrier plate 305.

Referring to FIG. 10, a substrate 101 is provided. The substrate includes a bonding surface 101a.

The substrate 101 is used for realizing bonding to the device chip 201 and bonding to the first interconnect chip 301, so as to realize packaging integration and electrical integration of the device chip 201, the first interconnect chip 301 and the substrate 101. The substrate 101 is also used for providing a process operation basis for realizing bonding to the device chip 201 and bonding to the first interconnect chip 301.

Specifically, the bonding surface 101a of the substrate 101 is a process operation platform.

In this form, the substrate 101 is a PCB (printed circuit board).

Referring to FIG. 11, the first side 201a of the device chip 201 and the side of the first interconnect chip 301 facing away from the second interconnect chip 401 are bonded to the bonding surface 101a of the substrate 101. The first side 201a of the device chip 201 is electrically connected to the substrate 101, and the first interconnect chip 301 is electrically connected to the substrate 101.

In this form, the first side 201a of the device chip 201 is bonded to the bonding surface 101a to realize electrical connection between the first side 201a of the device chip 201 and the substrate 101. The device chip 201 is electrically connected to the first interconnect chip 301 through the second interconnect chip 401 located on the second side 201b of the device chip 201, and the first interconnect chip 301 is electrically connected to the substrate 101, so as to realize electrical connection between the second side 201b of the device chip 201 and the substrate 101, so that the first side 201a and the second side 201b of the device chip 201 opposite to each other can both be electrically connected to the substrate 101, and accordingly the first side 201a and the second side 201b of the device chip 201 can both be electrically connected to the outside through the substrate 101, thereby improving the integration level of the packaging structure.

In addition, in this form, the electrical connection between the second side 201b of the device chip 201 and the first interconnect chip 301 is realized through the isolated second interconnect chip 401, which is beneficial to improve the flexibility of packaging and save the cost.

During the actual process, this form is particularly applicable to the case where a buried power rail (BPR) structure and a power delivery network (PDN) structure are used, which has high requirements for chip size and integration level.

In an example, the first side 201a of the device chip 201 is bonded to the bonding surface 101a to realize signal communication between the first side 201a of the device chip 201 and the substrate 101. The device chip 201 is electrically connected to the first interconnect chip 301 through the second interconnect chip 401 located on the second side 201b of the device chip 201, and the first interconnect chip 301 is electrically connected to the substrate 101, so as to realize electrical connection between the second side 201b of the device chip 201 and the substrate 101, thereby realizing power supply to the device chip 201 through the substrate 101.

In this form, after realizing the packaging integration of the device chip 201 with the first interconnect chip 301 and the second interconnect chip 401, the first side 201a of the device chip 201 and the side of the first interconnect chip 301 facing away from the second interconnect chip 401 are bonded to the bonding surface 101a of the substrate 101, so that the device chip 201, the first interconnect chip 301 and the second interconnect chip 401 are firstly fixed as an integral structure and then the integral structure is bonded to the substrate 101, which is beneficial to improve the packaging effect.

In this form, in the step of bonding the first side 201a of the device chip 201 and the side of the first interconnect chip 301 facing away from the second interconnect chip 401 to the bonding surface 101a of the substrate 101, the first interconnection structure 311 is electrically connected to the substrate 101.

In an example, the step of bonding the first side 201a of the device chip 201 and the side of the first interconnect chip 301 facing away from the second interconnect chip 401 to the bonding surface 101a of the substrate 101 includes: forming second conductive bumps 111 on the first side 201a of the device chip 201 and the side of the first interconnect chip 301 facing away from the second interconnect chip 401, and/or, on the bonding surface 101a of the substrate 101; and realizing bonding of the device chip 201 to the substrate 101 and bonding of the first interconnect chip 301 to the substrate 101 through the second conductive bumps 111. The second conductive bumps 111 electrically connect the device chip 201 to the substrate 101 and electrically connect the first interconnect chip 301 to the substrate 101.

The second conductive bumps 111 are used for realizing electrical connection between the substrate 101 and the device chip 201 and realizing electrical connection between the first interconnect chip 301 and the substrate 101.

In this form, a material of the second conductive bump 111 includes one or more of tin, copper, aluminum, tungsten, cobalt, nickel, titanium, tantalum, titanium nitride and tantalum nitride. In an example, the material of the second conductive bump 111 is tin.

For example, the second conductive bump 111 may be C4 (Controlled Collapse Chip Connection), and has excellent electrical properties and thermal characteristics. Moreover, in a case of the same pitch between the second conductive bumps 111, the I/O number can be very high, and not limited by the size of the redistribution structure. Besides, the second conductive bump is suitable for mass production, and the size and weight are greatly reduced.

In other forms, the second conductive bump may be a ubump.

In this form, after bonding the first side 201a of the device chip 201 and the side of the first interconnect chip 301 facing away from the second interconnect chip 401 to the bonding surface 101a of the substrate 101, the packaging method further includes: filling a gap between the adjacent second conductive bumps 111 with a second sealing layer 511. The second sealing layer 511 covers the second conductive bumps 111.

The second sealing layer 511 is used for realizing sealing between the device chip 201 and the substrate 101 and sealing between the first interconnect chip 301 and the substrate 101, and also used for sealing the second conductive bumps 111.

In an example, the second sealing layer 511 is an underfill.

In this form, after bonding the second interconnect chip 401 to the device chip 201 and the first interconnect chip 301, the packaging method further includes: forming third conductive bumps 131 on a surface of one side of the substrate 101 facing away from the bonding surface 101a. The third conductive bumps 131 are used for realizing electrical connection between the packaging structure and an external circuit.

The electrical connection between the packaging structure and the external circuit is realized through the third conductive bumps 131, so as to realize electrical connection between both the front side and the back side of the device chip 201 to the external circuit.

In this form, a material of the third conductive bump 131 includes one or more of tin, copper, aluminum, tungsten, cobalt, nickel, titanium, tantalum, titanium nitride and tantalum nitride. In an example, the material of the third conductive bump 131 is tin.

For example, the third conductive bump 131 may be C4 (Controlled Collapse Chip Connection), and has excellent electrical properties and thermal characteristics. Moreover, in a case of the same pitch between the third conductive bumps 131, the I/O number can be very high, and not limited by the size of the redistribution structure. Besides, the third conductive bump is suitable for mass production, and the size and weight are greatly reduced.

In other forms, the third conductive bump may be a ball grid array (BGA) structure.

Although the disclosure has been described above, the disclosure is not limited thereto. Any person skilled in the art can make various changes and modifications without departing from the spirit and scope of the disclosure, therefore the scope of protection of the disclosure shall be subject to the scope defined by the claims.

What is claimed is:

1. A packaging structure, comprising:
a substrate, comprising a bonding surface;
a device chip, comprising a first side and a second side opposite to the first side, the first side of the device chip being bonded to the bonding surface and electrically connected to the substrate, and the second side of the device chip comprising a first chip area and a second chip area adjacent to the first chip area;
a first interconnect chip, bonded to the bonding surface at a side portion of the device chip and electrically connected to the substrate; and
a second interconnect chip, bonded to the first chip area of the device chip and the first interconnect chip, the second interconnect chip being electrically connected to the first interconnect chip and the device chip, and the second interconnect chip exposing the second chip area.

2. The packaging structure according to claim 1, wherein the first side is a front side of the device chip, and the second side is a back side of the device chip.

3. The packaging structure according to claim 1, wherein the packaging structure further comprises:
a first packaging layer, covering side walls of the device chip and the first interconnect chip.

4. The packaging structure according to claim 1, wherein the packaging structure further comprises:
a heat sink, attached to the second chip area of the device chip.

5. The packaging structure according to claim 4, wherein the packaging structure further comprises:
a second packaging layer, located on the first packaging layer and covering the second interconnect chip and a side wall of the heat sink, the second packaging layer exposing the heat sink.

6. The packaging structure according to claim 4, wherein a material of the heat sink comprises silicon.

7. The packaging structure according to claim 1, wherein a top surface of the first interconnect chip is flush with the second side of the device chip.

8. The packaging structure according to claim 1, wherein the packaging structure further comprises:
first conductive bumps, located between the device chip and the second interconnect chip and between the first interconnect chip and the second interconnect chip, electrically connecting the device chip to the second interconnect chip, and electrically connecting the first interconnect chip to the second interconnect chip; and
a first sealing layer, filling a gap between adjacent first conductive bumps and covering the first conductive bumps.

9. The packaging structure according to claim 1, wherein the packaging structure further comprises:
second conductive bumps, located between the device chip and the substrate and between the first interconnect chip and the substrate, electrically connecting the device chip to the substrate, and electrically connecting the first interconnect chip to the substrate; and
a second sealing layer, filling a gap between adjacent second conductive bumps and covering the second conductive bumps.

10. The packaging structure according to claim 1, wherein a first interconnection structure running through the first interconnect chip is formed in the first interconnect chip, and the substrate is electrically connected to the second interconnect chip bonded to the first interconnect chip through the first interconnection structure.

11. The packaging structure according to claim 1, wherein a second interconnection structure is formed in the second interconnect chip, and the second interconnect chip is electrically connected to the device chip through the second interconnection structure.

12. The packaging structure according to claim 1, wherein the second interconnect chip comprises a chip bridge or a chip comprising a plurality of re-distributed layers.

13. A packaging method, comprising:
providing a carrier plate, the carrier plate comprising a first area and a second area;
providing a first interconnect chip;
bonding the first interconnect chip to the carrier plate in the first area;
providing a device chip, comprising a first side and a second side opposite to the first side, the second side of the device chip comprising a first chip area and a second chip area adjacent to the first chip area;
bonding the first side of the device chip to the carrier plate in the second area, the first chip area of the device chip being adjacent to the first interconnect chip;
providing a second interconnect chip;
bonding the second interconnect chip to the first interconnect chip and the first chip area of the device chip, the second interconnect chip being electrically connected to the first interconnect chip and the device chip, and the second interconnect chip exposing the second chip area;
removing the carrier plate to expose the first side of the device chip and a side of the first interconnect chip facing away from the second interconnect chip;
providing a substrate, comprising a bonding surface; and
bonding the first side of the device chip and the side of the first interconnect chip facing away from the second interconnect chip to the bonding surface of the substrate, the first side of the device chip being electrically connected to the substrate, and the first interconnect chip being electrically connected to the substrate.

14. The packaging method according to claim 13, wherein in the step of providing the device chip, the first side is a front side of the device chip, and the second side is a back side of the device chip.

15. The packaging method according to claim 13, wherein the packaging method further comprises:
after bonding the first interconnect chip to the carrier plate in the first area and bonding the first side of the device chip to the carrier plate and before bonding the second interconnect chip to the first interconnect chip and the first chip area of the device chip, forming a first packaging layer covering side walls of the first interconnect chip and the device chip on the carrier plate.

16. The packaging method according to claim 13, wherein the packaging method further comprises:
after bonding the first interconnect chip to the carrier plate in the first area and bonding the first side of the device chip to the carrier plate and before removing the carrier plate,
providing a heat sink, and
attaching the heat sink to the second chip area of the device chip.

17. The packaging method according to claim 16, wherein the packaging method further comprises:
after bonding the second interconnect chip to the first interconnect chip and the first chip area of the device chip and attaching the heat sink to the second chip area of the device chip and before removing the carrier plate, forming a second packaging layer covering the second interconnect chip and a side wall of the heat sink, the second packaging layer exposing the heat sink.

18. The packaging method according to claim 13, wherein after bonding the first interconnect chip to the carrier plate in the first area and bonding the first side of the device chip to the carrier plate, a top surface of the first interconnect chip is flush with the second side of the device chip.

19. The packaging method according to claim 13, wherein the step of bonding the second interconnect chip to the first interconnect chip and the first chip area of the device chip comprises:
forming first conductive bumps on the second interconnect chip, or on the first chip area of the device chip and a side of the first interconnect chip facing away from the carrier plate; and
realizing bonding of the second interconnect chip to the device chip and the first interconnect chip through the first conductive bumps, the first conductive bumps electrically connecting the second interconnect chip to the device chip and electrically connecting the second interconnect chip to the first interconnect chip.

20. The packaging method according to claim 13, wherein the step of bonding the first side of the device chip and the side of the first interconnect chip facing away from the second interconnect chip to the bonding surface of the substrate comprises:
forming second conductive bumps on the first side of the device chip and the side of the first interconnect chip facing away from the second interconnect chip, or on the bonding surface of the substrate; and
realizing bonding of the device chip to the substrate and bonding of the first interconnect chip to the substrate through the second conductive bumps, the second conductive bumps electrically connecting the device chip to the substrate and electrically connecting the first interconnect chip to the substrate.
